(19) United States
(12) Patent Application Publication
(10) Pub. No.: US 2026/0321524 A1
(43) Pub. Date: Oct. 15, 2026

(54) SENSOR SYSTEM FOR DETERMINING THE ARC BURNING DURATION, AND LOAD STAGE SWITCHING APPARATUS

(71) Applicant: Maschinenfabrik Reinhausen GmbH, Regensburg (DE)

(72) Inventors: Andreas Sachsenhauser, Mallersdorf (DE); Konrad Rädlinger, Tegernheim (DE); Lukas Koller, Schwandorf (DE)

(21) Appl. No.: 18/880,571

(22) PCT Filed: Jun. 20, 2023
(86) PCT No.: PCT/EP2023/066606

§ 371 Date: Jan. 2, 2025

(30) Foreign Application Priority Data
Jul. 14, 2022 (DE) 10 2022 117 590.1

(51) Int. Cl. H01H 9/00; G01R 31/327

(52) U.S. Cl. CPC H01H 9/0038; G01R 31/3274; H01H 2009/0061

(57) ABSTRACT

A sensor system for determining arc burning duration in a vacuum interrupter is provided. The system includes a measuring device and a sensor unit. The measuring device includes a receiver and a measuring apparatus. The sensor unit includes a voltage divider, an energy generator, an energy conversion unit, an evaluation unit and a transmitter. The sensor unit is configured to connect to a first contact and a second contact of the vacuum interrupter, and the sensor unit is connected to the measuring device via a signal transmitter.

### CROSS REFERENCE TO RELATED APPLICATIONS

This application is a U.S. National Phase application under 35 U.S.C. § 371 of International Application No. PCT/EP 2023/066606, filed on Jun. 20, 2023, and claims benefit to German Patent Application No. DE 10 2022 117 590.1, filed on Jul. 14, 2022. The International Application was published in German on Jan. 18, 2024 as WO 2024/012814 A 1 under PCT Article 21(2).

### FIELD

The disclosure relates to a sensor system for determining the arc burning duration and to an on-load tap-changer device.

### BACKGROUND

On-load tap-changers are used for uninterrupted switchover between different winding taps of an item of electrical equipment, such as a power transformer or a controllable reactor. Due to the fact that the switching elements such as vacuum interrupters and selector arms are always at high-voltage potential, these parts are generally not monitored. However, means and methods for monitoring these parts are desirable.

### SUMMARY

In an embodiment, the present disclosure provides a sensor system for determining arc burning duration in a vacuum interrupter. The system includes a measuring device and a sensor unit. The measuring device includes a receiver and a measuring apparatus. The sensor unit includes a voltage divider, an energy generator, an energy conversion unit, an evaluation unit and a transmitter. The sensor unit is configured to connect to a first contact and a second contact of the vacuum interrupter, and the sensor unit is connected to the measuring device via a signal transmitter.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a tap-changing transformer comprising an on-load tap-changer device, according to embodiments of the present disclosure; and

FIG. 2 shows a sensor unit, according to embodiments of the present disclosure.

### DETAILED DESCRIPTION

In accordance with an embodiment, of the present disclosure provides a sensor system that enables accurate and cost-effective monitoring of vacuum interrupters.

The disclosure proposes a sensor system for determining the arc burning duration in a vacuum interrupter, comprising
a measuring device comprising a receiver and a measuring apparatus;
a sensor unit comprising a voltage divider, an energy generator, an energy conversion unit, an evaluation unit and a transmitter; wherein
the sensor unit is able to be connected to a first contact and a second contact of a vacuum interrupter;
the sensor unit is connected to the measuring device via a signal transmitter.

Connecting the sensor unit directly to a vacuum interrupter makes it possible to determine the arc burning duration. The voltage divider of the sensor unit detects the voltage present at the vacuum interrupter when an arc is produced in the vacuum interrupter, or taps off the voltage present at the vacuum interrupter. A detected arc is transmitted to the measuring device in the form of an output signal via the evaluation unit and the transmitter and is evaluated by the measuring apparatus. Depending on the duration of the output signal, it is possible to infer how long the arc burning duration lasts. The energy generator autonomously supplies energy to the sensor unit. This is particularly advantageous because the sensor unit is at high-voltage potential. Complicated cabling for an energy supply is not necessary.

The transmitter and the receiver may be configured in any desired manner, for example, the transmitter may be in the form of a diode and the receiver may be in the form of a photodiode. In such an embodiment, the signal transmitter is then in the form of a fiber-optic cable. Furthermore, depending on the configuration of the transmitter, the receiver and the signal transmitter, the signal transmission is able to be effected in any desired manner, for example by radio, Bluetooth, WLAN, etc.

By way of example, the energy generator may be in the form of a current transformer or a voltage transformer or a transformer according to the energy harvesting principle. Said energy generator is preferably arranged inside the tap-changing transformer, preferably at high-voltage potential.

The evaluation unit may furthermore be in the form of a rectifier network. The evaluation unit is preferably connected to the energy generator via the energy conversion unit in order to supply energy to the sensor unit. The voltage divider of the sensor unit is connected to the first contact and the second contact of the vacuum interrupter in order to detect the arc burning duration.

The sensor unit is designed and set up to be connected to a vacuum interrupter of an on-load tap-changer, in particular, the sensor unit is designed and set up to be connected to a first and a second contact of the vacuum interrupter.

The vacuum interrupter may be configured in any desired manner and may have a first contact and a second contact. The contacts extend outward from the interior of the vacuum interrupter. In this case, the sensor unit may be connected directly to the contacts of the vacuum interrupter or to conductive elements such as cables, which are connected to the contacts.

The disclosure furthermore proposes an on-load tap-changer device, comprising
an on-load tap-changer comprising a vacuum interrupter;
a sensor system comprising a measuring device and a sensor unit for determining the arc burning duration in the vacuum interrupter; wherein
the sensor unit is connected to a first contact and to a second contact of the vacuum interrupter;
the measuring device is connected to the sensor unit via a signal transmitter.

The on-load tap-changer device allows the arc burning duration inside a vacuum interrupter of the on-load tap-changer to be determined. It is therefore possible to ensure that the arc inside the on-load tap-changer is extinguished during actuation. Furthermore, on the basis of this information, the actuation of the on-load tap-changer is able to be adjusted via the drive, with the result that the arc burning duration is as short as possible. The on-load tap-changer device is of particularly compact construction due to the sensor unit being arranged in close proximity to the vacuum interrupter. Furthermore, energy is supplied to the sensor unit autonomously by a dedicated energy generator.

The on-load tap-changer device furthermore has a drive for actuating the on-load tap-changer, wherein the drive is controlled by way of the measuring device of the sensor system. The drive is arranged on the outside of the tap-changing transformer. The measuring device may be arranged on the outside of the tap-changing transformer or inside the tap-changing transformer. Furthermore, the measuring device may be arranged in the on-load tap-changer head. The measuring device and the drive are, however, always at ground potential. The sensor unit is arranged inside the tap-changing transformer or inside the on-load tap-changer in close proximity to the vacuum interrupter. “Inside the tap-changing transformer” or “inside the on-load tap-changer” means within the housing of the tap-changing transformer or within or on the housing of the on-load tap-changer. In particular, the sensor unit is arranged in the oil compartment of the diverter switch. The diverter switch is part of the on-load tap-changer and is also arranged inside a tap-changing transformer, i.e. in housing thereof. The sensor unit and the vacuum interrupter are always at high-voltage potential. This also applies to the diverter switch.

The disclosure is explained below in detail on the basis of exemplary embodiments with reference to the drawings.

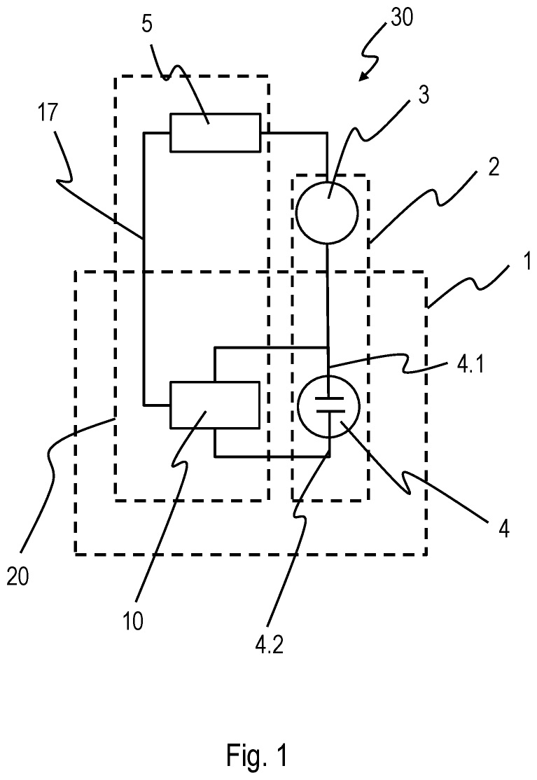

FIG. 1 shows a tap-changing transformer 1 comprising an on-load tap-changer device 30. The on-load tap-changer device 30 has an on-load tap-changer 2 and a sensor system 20. The on-load tap-changer 2 is connected to a drive 3 and is actuated thereby. The on-load tap-changer 2 has a diverter switch and a selector, which are not shown. Furthermore, the diverter switch, and therefore also the on-load tap-changer 2, have at least one vacuum interrupter 4, which is used for the switchover under load. A sensor unit 10 is connected to the vacuum interrupter 4. The sensor unit is used to detect or to determine the arc burning duration upon actuation, especially upon the vacuum interrupter 4 being opened. The sensor unit 10 is preferably arranged in the on-load tap-changer 4, in particular in the diverter switch or in close proximity to the vacuum interrupter 4. Furthermore, the sensor unit 10 is connected to a measuring device 5. The sensor unit 10 and the measuring device 5 form a sensor system 20 for detecting or determining the arc burning duration.

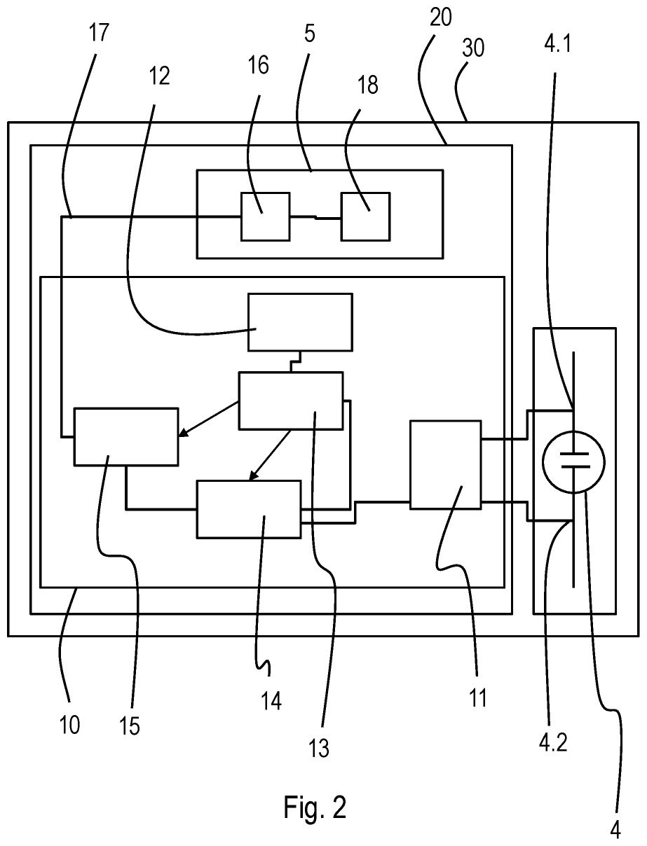

FIG. 2 shows a detailed view of the sensor unit 10. The sensor unit 10 is connected to the vacuum interrupter 4 of the on-load tap-changer 2 at a first contact 4.1 and at a second contact 4.2 of the vacuum interrupter 4. The sensor unit 10 has a voltage divider 11 that is set up and designed to reduce the high voltage across the vacuum interrupter 10 to a lower voltage. In particular, the voltage divider 11 of the sensor unit is connected to the first contact 4.1 and to the second contact 4.2 of the vacuum interrupter 4.

Furthermore, an energy generator 12 is provided. Said energy generator provides energy for the operation of the sensor unit 10. The energy generator 12 may be, for example, in the form of a current transformer, voltage transformer or other transformer, which functions according to the energy harvesting principle (by means of tapping off temperature, mechanical vibrations, electric or magnetic fields). The energy generator 12 is either a permanent part of the sensor unit 10, i.e. is integrated, or is electrically conductively connected thereto.

Furthermore, an energy conversion unit 13 is provided. Said energy conversion unit adapts the energy obtained from the energy generator 12 according to the specifications of the other components, i.e. voltage and current, to the needs and requirements of the evaluation unit 14 and the transmitter 15. Furthermore, the energy conversion unit 13 generates a reference voltage. The energy conversion unit 13 may, for example, be in the form of a rectifier network and, for example, also comprise capacitors or coils for the buffer-storage of energy.

The evaluation unit 14, which, for example, is in the form of a comparator network, is connected to the voltage divider 11 and the energy conversion unit 13. The evaluation unit 14 is designed and set up to evaluate the voltage detected or tapped off by the voltage divider 11. In this case, the voltage tapped off by the voltage divider 11 is used as a basis to determine whether an arc is present in the vacuum interrupter 4 during a switchover. By way of example, in the case of a tapped-off voltage of 15 m V to 25 m V, an arc is present in the vacuum interrupter. This voltage range is given here as an example. The tapped-off voltage range is dependent, among other things, on the nature of the individual parts of the vacuum interrupter 4. The evaluation unit 14 is set up and designed to detect a certain voltage value or a voltage range, to process or compare it with a reference voltage, and to generate an output signal therefrom.

Furthermore, the evaluation unit 14 is connected to a transmitter 15. Said transmitter transmits the output signals generated by the evaluation unit 14 to the measuring device 5. The transmitter 15 is preferably in the form of a diode. The measuring device 5, which is at ground potential, has a receiver 16 that is in the form of a diode or photodiode. In the example shown here, the transmitter 15 and the receiver 16 are connected to one another via a fiber-optic cable that is used as a signal transmitter 17. Depending on the configuration of the transmitter 15, the receiver 16 and the signal transmitter 17, the signal transmission is able to be effected in any desired manner, for example by radio, Bluetooth, WLAN, etc. The measuring device 5 may be arranged inside the tap-changing transformer 1 below the on-load tap-changer cover or else on the outside of the tap-changing transformer 1, for example in the motor drive or voltage regulator.

The measuring device 5 also has a measuring apparatus 18, using which the received output signal is able to be evaluated. The measuring device 18 is designed and set up to process and evaluate the output signal and may, for example, have a corresponding processor and a memory.

When the on-load tap-changer 2 is actuated, a vacuum interrupter 4 of the on-load tap-changer 2 is opened by means of the drive 3. Since a sinusoidal current generally flows through the on-load tap-changer 2, and therefore through the vacuum interrupter 4, arcs may be produced between the contacts when the vacuum interrupter 4 is opened. These are generally extinguished at the next current zero crossing or when the contacts of the vacuum interrupter are far enough apart from one another. If the current is at its zero point when the opening occurs, no arc is produced. The sensor unit 10 is used to detect the arc burning duration. In this case, a voltage value or a voltage range from the voltage divider 11 is converted into an output signal in the evaluation unit 14 and transmitted via the transmitter 15 to the measuring device 5. The measuring apparatus 18 in the control device 5 measures the duration of the output signal and determines the arc burning duration therefrom. The duration of the output signal depends on, or is specified by, the arc burning duration. The measuring apparatus 18 is designed and set up to determine the arc burning duration from the output signal of the sensor unit 10.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE SIGNS

1 Tap-changing transformer
2 On-load tap-changer
3 Drive
4 Vacuum interrupter
4.1 First contact
4.2 Second contact
5 Measuring device
10 Sensor unit
11 Voltage divider
12 Energy generator
13 Energy conversion unit
14 Evaluation unit
15 Transmitter
16 Receiver
17 Signal transmitter
18 Measuring apparatus
20 Sensor system
30 On-load tap-changer device

1. A sensor system for determining the arc burning duration in a vacuum interrupter, comprising:
a measuring device comprising a receiver and a measuring apparatus;
a sensor unit comprising a voltage divider an energy generator, an energy conversion unit, an evaluation unit and a transmitter;
wherein
the sensor unit configured to connect to a first contact and a second contact of a the vacuum interrupter; and
the sensor unit is connected to the measuring device via a signal transmitter.

2. The sensor system as claimed in claim 1, wherein:
the transmitter a diode;
the signal transmitter is a fiber-optic cable; and
the receiver is in of a photodiode.

3. The sensor system as claimed in claim 1, wherein:
the energy generator at least one of a current transformer or a voltage transformer or a transformer according to an energy harvesting principle.

4. The sensor system as claimed in claim 1, wherein:
the evaluation unit) is a rectifier network.

5. The sensor system as claimed in claim 1, wherein:
the evaluation unit is connected to the energy generator via the energy conversion unit in order to supply energy to the sensor unit and generate a reference voltage.

6. The sensor system as claimed in claim 1, wherein:
the voltage divider of the sensor unit configured to connect the first contact and the second contact of a vacuum interrupter.

7. The sensor system as claimed in claim 1, wherein:
the voltage divider taps off a voltage present at the vacuum interrupter.

8. The sensor system as claimed in claim 7, wherein
the evaluation unit generates an output signal based on its reference voltage from the energy conversion unit and the voltage tapped off by the voltage divider; and
the evaluation unit transmits the output signal to the measuring device by means of the transmitter.

9. An on-load tap-changer device comprising:
an on-load tap-changer comprising a vacuum interrupter;
a sensor system comprising a measuring device and a sensor unit for determining arc burning duration in the vacuum interrupter;
wherein:
the sensor unit is connected to a first contact and to a second contact of the vacuum interrupter;
the measuring device is connected to the sensor unit via a signal transmitter.

10. The on-load tap-changer device as claimed in claim 9, comprising:
a drive for actuating the on-load tap-changer, wherein the drive is controlled by way of the measuring device of the sensor system.
